(19) United States
(12) Patent Application Publication
(10) Pub. No.: US 2013/0025676 A1
(43) Pub. Date: Jan. 31, 2013

(54) SOLAR CELL AND MANUFACTURING METHOD OF THE SAME

(71) Applicant: Jin Woo Lee, Seoul (KR)

(72) Inventor: Jin Woo Lee, Seoul (KR)

(73) Assignee: LG INNOTEK CO., LTD., Seoul (KR)

(21) Appl. No.: 13/640,403

(22) PCT Filed: Nov. 18, 2011
(86) PCT No.: PCT/KR2011/008857

§ 371 Date: Oct. 10, 2012

(30) Foreign Application Priority Data
Jan. 24, 2011 (KR) 10-2011-0006987

(51) Int. Cl. H01L 31/0236; H01L 31/18; H01L 31/0224

(52) U.S. Cl. 136/256; 438/98; 257/E31.124

(57) ABSTRACT

A solar cell is provided. The solar cell includes a transparent electrode layer on a substrate, a pattern layer on the transparent electrode layer, the pattern layer including a plurality of pattern parts having inclined side surfaces, a light absorption layer on the pattern layer, and a back surface electrode layer on the light absorption layer.

### TECHNICAL FIELD

Embodiments relate to a solar cell and a method of manufacturing the same.

### BACKGROUND ART

Solar cells convert solar energy into electric energy. The solar cells are being widely commercially used as demand for energy increases in recent years.

The solar cell may be classified into a super straight type and a sub straight type according to a structure thereof. The super straight type solar cell has a structure in which light is incident from a transparent substrate. Thus, the super straight type solar cell sequentially includes a light-transmitting substrate, a transparent electrode layer, a light absorption layer, a back surface electrode layer.

To improve photoelectric conversion efficiency of the solar cell, an area of a PN junction surface should increase. However, the light absorption layer constituting the PN junction surface is generally disposed parallel to the substrate. Thus, there is a limitation to maximize the photoelectric conversion efficiency.

### DISCLOSURE OF INVENTION

### Technical Problem

Embodiments provide a solar cell in which an effective area of a light absorption layer increases to improve photoelectric conversion efficiency and a method of manufacturing the same.

### Solution to Problem

In one embodiment, a solar cell includes: a transparent electrode layer on a substrate; a pattern layer on the transparent electrode layer, the pattern layer including a plurality of pattern parts having inclined side surfaces; a light absorption layer on the pattern layer; and a back surface electrode layer on the light absorption layer.

In another embodiment, a solar cell includes: a transparent electrode layer on a substrate; a pattern layer on the transparent electrode layer, the pattern layer including a plurality of pattern parts having inclined side surfaces; a light absorption layer on the pattern layer, the light absorption layer including a first pattern corresponding to the pattern parts; and a back surface electrode layer on the light absorption layer, the back surface electrode layer including a second pattern corresponding to the pattern parts.

In further another embodiment, a method of manufacturing a solar cell includes: forming a transparent electrode layer on a substrate; forming a pattern layer including a plurality of pattern parts having inclined side surfaces on the transparent electrode layer; forming a light absorption layer on the pattern layer; and forming a back surface electrode layer on the light absorption layer.

The details of one or more embodiments are set forth in the accompanying drawings and the description below. Other features will be apparent from the description and drawings, and from the claims.

### Advantageous Effects of Invention

In the solar cell according to the embodiments, the pattern layer including the pattern part may be disposed on the transparent electrode layer to increase the effective surface area of the light absorption layer disposed on the transparent electrode layer. Thus, the solar cell according to the embodiments may have the improved photoelectric conversion efficiency.

Also, light which is incident into the transparent electrode layer, but is not absorbed into the light absorption layer may be diffusively reflected by the side surface of the pattern part and absorbed again into the light absorption layer. That is, in the solar cell according to the embodiments, the diffuse reflection efficiency of light may be improved due to the pattern part to further improve the efficiency of the solar cell.

### BRIEF DESCRIPTION OF DRAWINGS

FIG. 1 is a sectional view of a solar cell according to an embodiment.

FIG. 2 is a plan view of a transparent electrode layer according to an embodiment.

FIG. 3 is a sectional view illustrating a main part of the transparent electrode layer according to an embodiment.

FIG. 4 is a graph illustrating efficiency of the solar cell according to an embodiment.

FIGS. 5 to 7 are sectional views illustrating a modified example of the transparent electrode layer according to an embodiment.

FIG. 8 is a sectional view of a solar cell according to another embodiment.

FIGS. 9 to 12 are sectional views illustrating a process of manufacturing the solar cell according to an embodiment.

### MODE FOR THE INVENTION

In the descriptions of embodiments, it will be understood that when a panel, a wire, a battery, a surface, or a pattern is referred to as being ‘on’ or ‘under’ another panel, wire, battery, surface, or pattern, it can be directly on or under another layer or substrate, or intervening layers may also be present. Further, the reference about ‘on’ and ‘under’ each component layer will be made on the basis of drawings. In addition, the sizes of elements and the relative sizes between elements may be exaggerated for further understanding of the present disclosure.

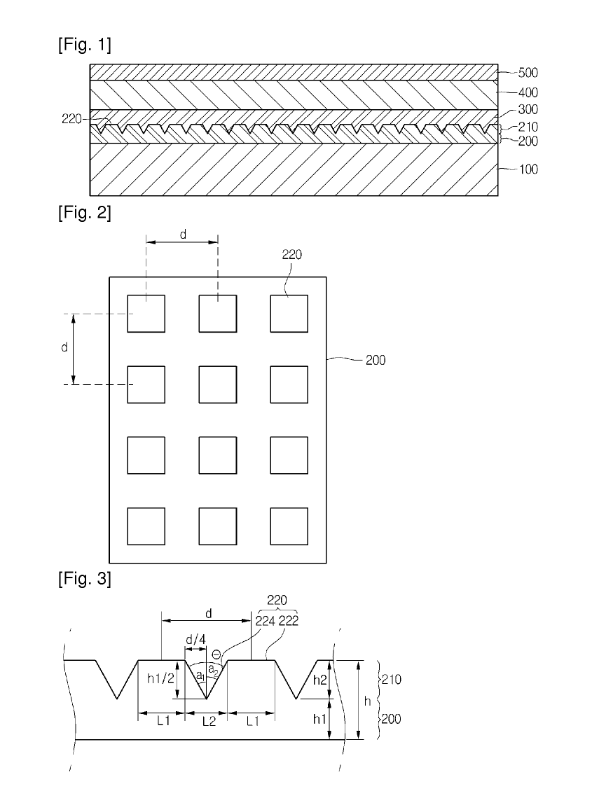

FIG. 1 is a sectional view of a solar cell according to an embodiment. FIG. 2 is a plan view of a transparent electrode layer according to an embodiment. FIG. 3 is a sectional view illustrating a main part of the transparent electrode layer according to an embodiment.

Referring to FIG. 1, a solar cell according to an embodiment includes a substrate 100, a transparent electrode layer 200 on the substrate 100, a pattern layer 210 on the transparent electrode layer 200, a buffer layer 300 on the pattern layer 210, a light absorption layer 400 on the buffer layer 300, and a back surface electrode layer 500 on the light absorption layer 400. Also, although not shown, a high-resistance buffer layer may be additionally disposed between the transparent electrode layer 200 and the buffer layer 300.

The substrate 100 may have a plate shape to support the transparent electrode layer 200, the pattern layer 210, the buffer layer 300, the light absorption layer 400, and the back surface electrode layer 500.

The substrate 100 may be transparent. Also, the substrate 100 may be rigid or flexible.

The substrate 100 may be an electrical insulator. For example, the substrate 100 may be a glass substrate, a plastic substrate, or a metal substrate. In detail, the substrate 100 may be a soda lime glass substrate containing sodium components. On the other hand, the substrate 100 may be formed of a ceramic material such as alumina, a stainless steel, or a flexible polymer.

The transparent electrode layer 200 may be formed of a light-transmitting conductive material. Also, the transparent electrode layer 200 may have N-type semiconductor characteristics. Here, the transparent electrode layer 200 together with the buffer layer 300 may form an N-type semiconductor layer. Also, the transparent electrode layer 200 may adhere to the light absorption layer 400 that is a P-type semiconductor layer to form a PN junction.

For example, the transparent electrode layer 200 may be formed of zinc oxide which is doped with aluminum. However, the present disclosure is not limited to the material of the transparent electrode layer 200. For example, the transparent electrode layer 200 may be formed of one of ZnO, SnO₂, and ITO which have high transmittance and conductivity. Also, the transparent electrode layer 200 may have a thickness of about 100 nm to about 500 nm.

The pattern layer 210 is disposed on the transparent electrode layer 200. The pattern layer 210 may include a plurality of pattern parts 220 having inclined side surfaces. The pattern layer 210 may effectively trap solar light incident into the substrate 100 to improve efficiency of the solar cell. The pattern layer 210 having the above-described structure will be described later in detail with reference to the accompanying drawings.

The buffer layer 300 is disposed on the transparent electrode layer 200. The buffer layer 300 may reduce an energy gap difference between the light absorption layer 400 and the back surface electrode layer 500 that will be described later.

The buffer layer 300 may include cadmium sulfide, ZnS, In_{X}S_{Y}, and In_{X}Se_{Y} Zn(O,OH). The buffer layer 300 may have a thickness of about 50 nm to about 150 nm. Also, the buffer layer 300 may have an energy band gap ranging from about 2.2 eV to about 2.4 eV.

Alternatively, the high-resistance buffer layer may be additionally disposed on the buffer layer 300. The high-resistance buffer layer may have a high resistance to prevent the buffer layer 300 from electrically contacting the transparent electrode layer 200 or from being damaged by impacts. The high-resistance buffer layer may be formed of zinc oxide (i-ZnO) which is undoped with impurities. The high-resistance buffer layer may have an energy band gap ranging from about 3.1 eV to about 3.3 eV.

The light absorption layer 400 is disposed on the buffer layer 300. The light absorption layer 400 may be formed of a group I-III-VI-based compound, e.g., at least one of CIGS, CIS, CGS, and CdTe. For example, the light absorption layer 140 may be formed of at least one selected from the group of CdTe, CuInSe₂, Cu(In,Ga)Se₂, Cu(In,Ga)(Se,S)₂, Ag(InGa)Se₂, Cu(In,Al)Se₂, and CuGaSe₂.

The back surface electrode layer 500 is disposed on the light absorption layer 400. The back surface electrode layer 500 may be a conductive layer. The back surface electrode layer 500 may be formed of one of molybdenum (Mo), gold (Au), aluminum (Al), chrome (Cr), tungsten (W), and copper (Cu), but is not limited thereto.

As shown in FIGS. 2 and 3, the pattern layer 210 is disposed on the transparent electrode layer 200. The pattern layer 210 is disposed on one surface of the transparent electrode layer 200. Specifically, the pattern layer 210 directly contacts a top surface of the transparent electrode layer 200. The pattern layer 210 and the transparent electrode layer 200 may be integrated with each other, but is not limited thereto.

The pattern layer 210 includes the plurality of pattern parts 220 having the inclined side surfaces. The plurality of pattern parts 220 protrude upward from the transparent electrode layer 200. For example, the pattern parts 220 may have a waffle, but is not limited thereto.

As shown in FIGS. 2 and 3, the plurality of pattern parts 220 may be spaced a predetermined distance from each other on the transparent electrode layer 200. That is, the plurality of pattern parts 220 may be regularly arranged on the transparent electrode layer 200. However, the present disclosure is not limited thereto. For example, the plurality of pattern parts 220 may be irregularly disposed on the transparent electrode layer 200. In more detail, it is preferable that the plurality of pattern parts 200 may be regularly arranged on the transparent electrode layer 200.

Each of the plurality of pattern parts 220 has a horizontal surface 222 parallel to the substrate 100 and an inclined side surface 224. The inclined side surface 224 may be inclined at a predetermined angle with respect to the transparent electrode layer 200 or the substrate 100. That is, the side surface 224 of the pattern part 220 may be inclined downward toward the outside.

The plurality of pattern parts 220 are connected to each other by the inclined side surfaces 224. In more detail, an end of a lower portion of the inclined side surface 224 of one pattern part 220 is connected to an end of a lower portion of the inclined side surface 224 of the other pattern part 220 spaced from the one pattern part 220. Through the above-described structure, the pattern parts 220 are connected to the each other.

Each of the pattern parts 220 has a height h₂ corresponding to a thickness h₁ of the transparent electrode layer 200. For example, the pattern part 220 may have a height h₂ greater by about 0.5 times to about 1.5 times than a thickness h₁ of the transparent electrode layer 200, but is not limited thereto. In more detail, the pattern part 220 may have a height h₂ equal to a thickness h₁ of the transparent electrode layer 200, but is not limited thereto. Also, the pattern part 220 may have a length L₁ corresponding to a length L₂ between the pattern parts 220. Also, a distance d between centers of the pattern parts 220 may range from about 2 μm to about 4 μm, but is not limited thereto.

An angle θ subtended by the pattern parts 220, i.e., an angle θ subtended by the side surfaces 224 of the pattern parts 220 may be determined according to the sum h of thicknesses of the transparent electrode layer 200 and the pattern layer 210 and the distance d between the centers of the pattern parts 220. In more detail, an angle θ subtended by the pattern parts 220 may be determined by following Equation 1.

[Equation 1]

θ=aᵢ+a₂

Here, when the side surfaces 224 of the pattern parts 220 have the same height, a₁ and a₂ may have the same angle. Thus, an angle θ subtended between the pattern parts 200 may be determined by following Equations 2 to 4.

$$\begin{matrix}⊖ = {a}_{1} X 2 & [ Equation 2 ] \\ {a}_{1} = tan \frac{{}_{- 1} ( d / 4 )}{( h / 2 )} = \frac{( d )}{( 2 h )} & [ Equation 3 ] \\ ⊖ = tan \frac{{}_{- 1} d}{h} & [ Equation 4 ]\end{matrix}$$

Thus, it is preferable that an angle θ between the final pattern parts is less than that determined through Equation 4.

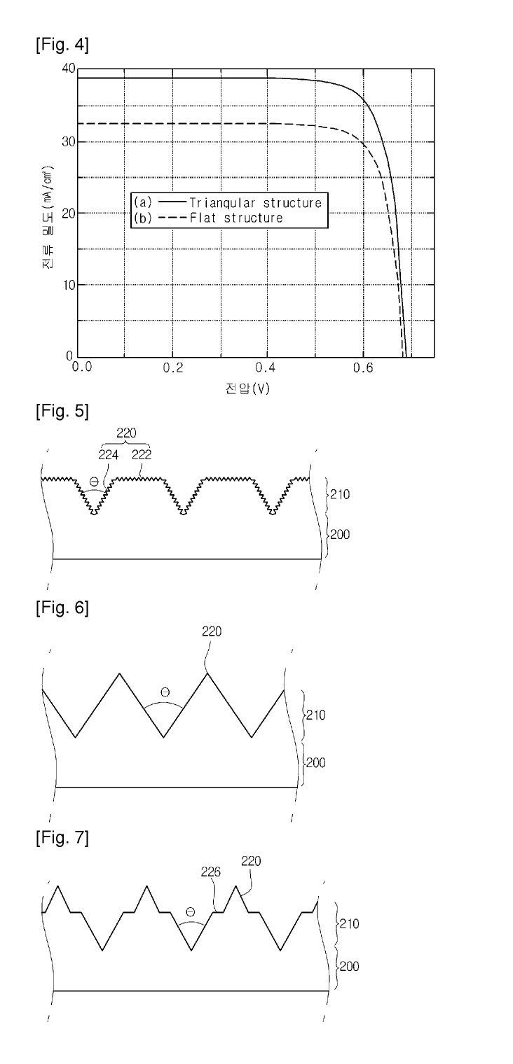

FIG. 4 is a graph illustrating efficiency of the solar cell according to an embodiment (a) and a comparative example (b). In more detail, FIG. 4 is a graph illustrating a correlation between a current density and a voltage of a solar cell (a) including a pattern layer according to an embodiment and the related-art solar cell (b). Referring to FIG. 4, the solar cell (a) including a pattern layer 210 according to an embodiment may have efficiency greater by about 20% than that of the related-art solar cell (b) in which the pattern layer 210 is not provided.

That is, it may be seen that the solar cell (a) according to an embodiment includes the pattern layer 210 on a transparent electrode layer 200 to increase an effective area thereof, thereby improving efficiency. Specifically, referring to Equations 1 to 4, the pattern layer 210 may be optimized in structure to increase light trapping performance, thereby significantly improving the efficiency of the solar cell when compared to an existing structure.

FIGS. 5 to 7 are sectional views illustrating a modified example of the transparent electrode layer 200 according to an embodiment. Referring to FIG. 5, a plurality of pattern parts 220 having a waffle structure may be disposed on the transparent electrode layer 200 to form a pattern layer 210. A top surface 222 of each of the pattern parts 220 may be parallel to a substrate 100, and a side surface 224 of each of the pattern parts 220 may be inclined with respect to the transparent electrode layer 200. Also, a side surface of one pattern part may be connected to a side surface of the other pattern part spaced from the one pattern. Thus, the plurality of pattern parts 220 may have side surfaces inclined at a predetermined angle. Here, an angle θ subtended by the plurality of pattern parts 220 may be determined according to a thickness of the transparent electrode layer 200 and a distance between centers of the pattern parts 220. Also, the angle θ subtended by the pattern parts 220 may be obtained through the above-described method.

Referring to FIG. 5, a roughness may be additionally disposed on a surface of each of the pattern parts 220. That is, the roughness may be further disposed on the top surface 222 and the side surface 224 of the pattern part 220 to increase an effective surface area. The roughness may have various shapes. For example, the roughness may have one of a polygonal shape, globular shape, a hemisphere shape, an oval shape and combinations thereof in section. Also, the roughness may be regularly or irregularly disposed on the surface of the pattern part 220.

As described above, the pattern layer 210 including the roughness disposed on the transparent electrode layer 200 may further increase the effective area of the solar cell to significantly improve the efficiency of the solar cell.

As shown in FIG. 6, a pattern layer 210 including only a plurality of pattern parts 220 having side surfaces inclined at a predetermined angle may be disposed on a transparent electrode layer 200 according to an embodiment. Referring to FIG. 6, an upper portion of each of the pattern parts 220 may have a triangular shape. Also, the pattern parts may have inclined side surfaces. Here, an angle θ subtended by the plurality of pattern parts 220 may be determined according to a thickness of the transparent electrode layer 200 and a distance between centers of the pattern parts 220. According to the above-described structure, the plurality of pattern parts 220 may be disposed by a predetermined distance to improve efficiency of the solar cell. Specifically, the pattern part 220 may have only the inclined side surfaces to increase diffuse reflection of light, thereby further improving the efficiency of the solar cell.

Referring to FIG. 7, the solar cell according to an embodiment may additionally include a stepped part 226. That is, a pattern layer 210 on which a plurality of pattern parts 220 having a waffle structure is disposed may be disposed on the transparent electrode layer 200. A side surface of the pattern part 220 may have the stopped part 226. As shown in FIG. 7, the stepped part 226 may include a horizontal part. On the other hand, the stepped part 226 may include a vertical part. Although one stepped part 226 is provided on the side surface of the pattern part 220 in FIG. 7, the present disclosure is not limited thereto. For example, two or more stepped parts may be provided on the side surface of the pattern part 220. Also, although an upper portion of the pattern part 220 has a mountain shape in FIG. 7, the present disclosure is not limited thereto. For example, the upper portion of the pattern part 220 may be parallel to the substrate 100.

According to the above-described structure, one or more stepped parts 226 may be disposed on the side surface of the pattern part 220 to further increase an effective surface area of the solar cell, thereby improving the efficiency of the solar cell.

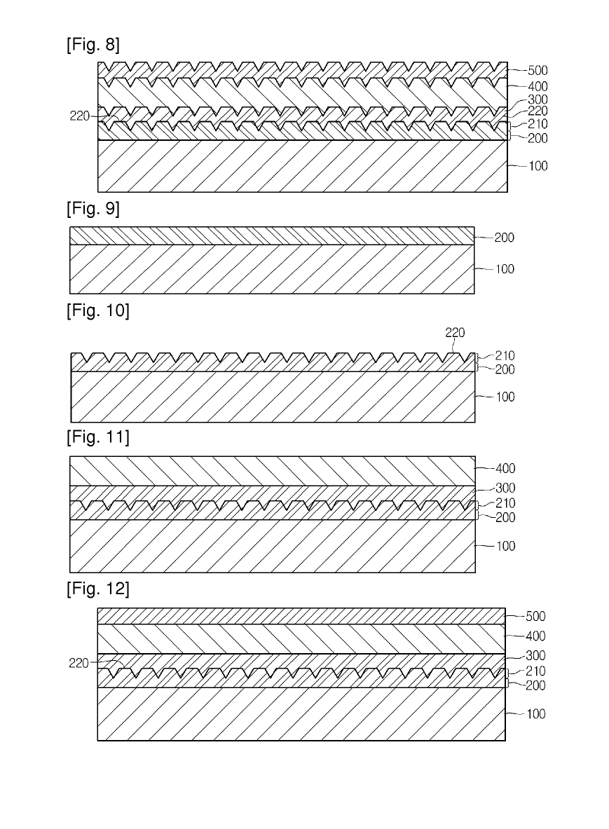

FIG. 8 is a sectional view of a solar cell according to another embodiment. Referring to FIG. 8, a solar cell according to another embodiment includes a transparent electrode layer 200 on a substrate 100, a pattern layer 210 disposed on the transparent electrode layer 200 and including a plurality of pattern parts 220 having inclined side surfaces, a buffer layer 300 disposed on the pattern layer 210 and including a third pattern corresponding to each of the pattern parts 220, a light absorption layer 400 disposed on the buffer layer 300 and including a first pattern corresponding to each of the pattern parts 220, and a back surface electrode layer 500 disposed on the light absorption layer 400 and including a second pattern corresponding to each of the pattern parts 220. Each of the first to third patterns may correspond to the pattern part 220. That is, each of the first to third patterns may have the same shape as that of the pattern part 220. For example, each of the first to third patterns may have a waffle shape, but is not limited thereto.

That is, the solar cell according to another embodiment includes the pattern layer 210 on the transparent electrode layer 200. Thus, each layer disposed on the pattern layer 210 may have a structure corresponding to that of the pattern layer 210.

FIGS. 9 to 12 are sectional views illustrating a process of manufacturing a solar cell according to an embodiment. The manufacturing method will be described with reference to the above-described descriptions with respect to the solar cell. The above-described descriptions with respect to the solar cell may be applied to the description with respect to the manufacturing method according to another embodiment.

Referring to FIG. 9, when a substrate 100 is prepared, a transparent electrode layer 200 is formed on one surface of the substrate 100. The transparent electrode layer 200 may be deposited on the substrate 100 through a sputtering process using AZO. Also, the transparent electrode layer 200 may be deposited at a thickness of about 2 μm to about 4 μm, but is not limited thereto.

Then, as shown in FIG. 10, a pattern layer 210 is formed on the transparent electrode layer 200. A portion of the transparent electrode layer 200 may be etched to form the pattern layer 210. In more detail, a portion of an upper portion of the transparent electrode layer 200 may be etched to form the pattern layer 210. That is, the transparent electrode layer 200 and the pattern layer 210 may be integrated with each other.

For example, a mask may be disposed on the transparent electrode layer 200 to perform an exposure process and/or a wet etching process, thereby forming the pattern layer 210. Here, the wet etching process may be performed at the same vertical and horizontal etch rate to form an inclined surface 224 of the pattern layer 210. That is, the inclined surface 224 may be naturally formed through the inclination etching in the wet etching process.

Although the wet etching process is described as an example for forming the pattern layer 210 so far, the present disclosure is not limited thereto. For example, various etching processes typically used in the art may be performed as the method for forming the pattern layer 210. For example, a physical vapor deposition (PVD) or chemical vapor deposition (CVD) process using plasma in place of the wet etching process may be performed to the inclined surface 224 of the pattern layer 210, but is not limited thereto.

Referring to FIG. 11, a buffer layer 300 and a light absorption layer 400 are formed on the transparent electrode layer 200 on which the pattern layer 210 is formed.

A sputtering process or a chemical bath deposition (CBD) process may be performed to deposit cadmium sulfide, thereby forming the buffer layer 300.

The light absorption layer 400 may be formed of a group I-III-VI-based compound. In more detail, the light absorber 400 may be formed of a Cu(In, Ga)Se₂ (CIGS)-based compound. Alternatively, the light absorption layer 300 may be formed of a CuInSe₂ (CIS)-based compound or CuGaSe₂ (CIS)-based compound.

For example, to form the light absorption layer 400 on the buffer layer 300, a CIG-based metal precursor film may be formed on the buffer layer 300 using a Cu target, an In target, and a Ga target. Thereafter, the metal precursor film may react with Se through a selenization process to form the light absorption layer 400.

Alternatively, a co-evaporation process may be performed using Cu, In, Ga, and Se to form the light absorption layer 400.

Then, as shown in FIG. 12, a back surface electrode layer 500 is formed on the light absorption layer 400. Here, Mo may be deposited at a predetermined thickness, e.g., about 1 μm through the sputtering process to form the back surface electrode layer 500.

When the back surface electrode layer 500 is completely formed, the process of manufacturing the solar cell according to an embodiment may be completed.

Features, structures, and effects described in the above embodiments are incorporated into at least one embodiment of the present disclosure, but are not limited to only one embodiment. Moreover, features, structures, and effects exemplified in one embodiment can easily be combined and modified for another embodiment by those skilled in the art. Therefore, these combinations and modifications should be construed as falling within the scope of the present disclosure.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell comprising:
a transparent electrode layer on a substrate;
a pattern layer on the transparent electrode layer, the pattern layer comprising a plurality of pattern parts having inclined side surfaces;
a light absorption layer on the pattern layer; and
a back surface electrode layer on the light absorption layer.

2. The solar cell according to claim 1, wherein the plurality of pattern parts are connected to each other by the inclined side surfaces.

3. The solar cell according to claim 1, wherein each of the pattern part has a thickness greater by about 0.5 times to about 1.5 times than that of the transparent electrode layer.

4. The solar cell according to claim 1, wherein the plurality of pattern parts are regularly arranged.

5. The solar cell according to claim 1, wherein a roughness is additionally disposed on a surface of each of the pattern parts.

6. The solar cell according to claim 5, wherein the roughness has one of a polygonal shape, globular shape, a hemisphere shape, and an oval shape in section.

7. The solar cell according to claim 1, wherein a top surface of each of the pattern parts comprises a horizontal surface parallel to the substrate.

8. The solar cell according to claim 1, wherein the side surface of each of the pattern part comprises a stepped part.

9. The solar cell according to claim 1, wherein each of the side surfaces are inclined at an angle less than that determined through following Equation.
$$⊖ = tan \frac{{}_{- 1} d}{h}$$
(where, h represents the sum of thicknesses of the transparent electrode layer and the pattern layer, and d represents a distance between the pattern parts)

10. A solar cell comprising:
a transparent electrode layer on a substrate;
a pattern layer on the transparent electrode layer, the pattern layer comprising a plurality of pattern parts having inclined side surfaces;
a light absorption layer on the pattern layer, the light absorption layer comprising a first pattern corresponding to the pattern parts; and
a back surface electrode layer on the light absorption layer, the back surface electrode layer comprising a second pattern corresponding to the pattern parts.

11. The solar cell according to claim 10, wherein the plurality of pattern parts are connected to each other by the inclined side surfaces.

12. The solar cell according to claim 10, wherein each of the pattern part has a thickness greater by about 0.5 times to about 1.5 times than that of the transparent electrode layer.

13. The solar cell according to claim 10, wherein the plurality of pattern parts are regularly arranged.

14. The solar cell according to claim 10, wherein a roughness is additionally disposed on a surface of each of the pattern parts.

15. The solar cell according to claim 14, wherein the roughness has one of a polygonal shape, globular shape, a hemisphere shape, and an oval shape in section.

16. The solar cell according to claim 10, wherein each of the side surfaces are inclined at an angle less than that determined through fallowing Equation.
$$⊖ = tan \frac{{}_{- 1} d}{h}$$
(where h represents the sum of thicknesses of the transparent electrode layer and the pattern layer, and d represents a distance between the pattern parts)

17. A method of manufacturing a solar cell, the method comprising:
forming a transparent electrode layer on a substrate;
forming a pattern layer comprising a plurality of pattern parts having inclined side surfaces on the transparent electrode layer;
forming a light absorption layer on the pattern layer; and
forming a back surface electrode layer on the light absorption layer.

18. The method according to claim 17, wherein the pattern layer is formed by etching a portion of the transparent electrode layer.
